(19) United States
(12) Patent Application Publication
(10) Pub. No.: US 2025/0118525 A1
(43) Pub. Date: Apr. 10, 2025

(54) PARTICLE BEAM SYSTEM WITH COOLING SYSTEM

(71) Applicant: Carl Zeiss Microscopy GmbH, Jena (DE)

(72) Inventor: Andreas Schmaunz, Oberkochen (DE)

(21) Appl. No.: 18/910,558

(22) Filed: Oct. 9, 2024

(30) Foreign Application Priority Data
Oct. 10, 2023 (DE) 10 2023 127 609.3

(51) Int. Cl. H01J 37/20

(52) U.S. Cl. CPC H01J 37/20; H01J 2237/002; H01J 2237/2001; H01J 2237/24585

(57) ABSTRACT

A particle beam system comprises: an object mount for mounting an object to be examined; a particle beam source; a lens for focusing the particle beam; a detector; and a cooling system for cooling the object mount. The cooling system comprises: a coolant passage through the object mount; a supply port; an outlet; a switchover valve having two positions; a first connecting line connected to the coolant passage and the switchover valve; a second connecting line connected to the coolant passage and the switchover valve; and a cooling mechanism for cooling a portion of the first connecting line. In the first position, the switchover valve connects the supply port to the first connecting line and connects the outlet to the second connecting line. In the second position, the switchover valve connects the supply port to the second connecting line and connects the outlet to the first connecting line.

### CROSS-REFERENCE TO RELATED APPLICATION

This application claims benefit under 35 U.S.C. § 119 to German Application No. 10 2023 127 609.3, filed Oct. 10, 2023. The entire disclosure of this application is incorporated by reference herein.

### FIELD

The disclosure relates to a particle beam system having a cooling system and to a method of operating such a particle beam system.

### BACKGROUND

In some cases, the examination of microscopic structures of an object comprises recording particle-optical images by virtue of using a particle beam system that scans a region on the object using a particle beam. There can be a desire to keep a temperature of the object low for the purpose of recording the particle-optical image, especially in the case of biological and chemical objects. In this regard, use is usually made of an object mount for mounting the object in the particle beam system, the object mount being connected to a nitrogen cooling mechanism. For example, an object mount of this type is available under the product name “U.S. Plant Pat. No. 3,006 CoolLok” or “U.S. Plant Pat. No. 3,005 SEMCool” from Quorum Technologies Ltd, Laughton, United Kingdom.

Conventionally obtainable nitrogen comprises contaminations which, when nitrogen is used to cool the object amount, can be deposited in the nitrogen cooling mechanism on account of the low temperature. Such deposits can block nitrogen-conducting lines until, ultimately, desired cooling is no longer possible. Therefore, the cooling operation of the nitrogen cooling mechanism is terminated when desired, and the nitrogen is guided uncooled through the nitrogen cooling mechanism in order to remove the deposits.

However, removing the deposits usually takes several hours, during which the particle beam system cannot be used to record particle-optical images.

### SUMMARY

The present disclosure seeks to shorten a time used to remove the deposits.

A particle beam system is proposed, comprising an object mount for mounting an object to be examined, a particle beam source for creating a particle beam, a lens for focusing the particle beam on the object, a detector for detecting signals created at the object by the particle beam and a cooling system for cooling the object mount. The cooling system comprises a coolant passage through the object mount, having an inlet port and an outlet port; a supply port for feeding a gas; an outlet for removing the gas; a switchover valve having a first position and a second position; a first connecting line, the first end of which is connected to the inlet port of the coolant passage, and the second end of which is connected to the switchover valve; a second connecting line, the first end of which is connected to the outlet port of the coolant passage, and the second end of which is connected to the switchover valve; and a cooling mechanism for cooling at least a first portion of the first connecting line. In the first position, the switchover valve connects the supply port to the second end of the first connecting line and the outlet to the second end of the second connecting line. Moreover, in the second position, the switchover valve connects the supply port to the second end of the second connecting line and the outlet to the second end of the first connecting line.

This means that the particle beam system can be operated in two operating modes, specifically a cooling operation and a thawing operation. During cooling operation, the gas is cooled and thus cools the object mount by virtue of the cooled gas flowing through the latter. The aforementioned deposits are for example created by water which is contained in the gas and which freezes in the first cooled portion of the cooling system, specifically in the first portion of the first connecting line. The water frozen there can be removed by virtue of nitrogen flowing through the connecting lines uncooled during the thawing operation, hence thaws out the frozen water and removes the latter through the connecting lines. Which operating mode is carried out is set by the particle beam system by way of the switchover valve, which has the first position and the second position to this end. The switchover valve is connected to the connecting lines of the cooling system in such a way that during the thawing operation, i.e. in the second position of the switchover valve, gas flows through the connecting lines in a direction that is reversed in relation to the direction of the gas flow during the cooling operation. This can help prevent the gas from initially thawing out frozen water during the thawing operation and subsequently flowing through the still cooled object mount, as this can lead to the thawed out water freezing in the coolant passage of the object mount during the thawing operation and being thawed out again there. By reversing the flow direction of the gas during the thawing operation by way of the switchover valve, the gas initially flows through the object mount, then flows through the first portion of the first connecting line, whereby the deposits can be removed, and is then released into the environment without flowing through a cooled region of the cooling system again. This can help reduce an amount of time used to remove the deposits in the cooling system, and the aforementioned object is achieved.

It should be observed that the labels used of inlet port and output port of the coolant passage serve merely illustrative purposes and do not define any flow direction of the gas. For example, the operation used predominantly is the cooling operation in which the switchover valve is operated in the first position. Accordingly, the inlet port of the coolant passage is the port of the coolant passage through which the gas enters the coolant passage during cooling operation, and the outlet port of the coolant passage is the port through which the gas emerges from the coolant passage during the cooling operation. Particular attention should be drawn to the fact that the assignment of the inlet port and outlet port does not depend on the current operation of the switchover valve.

It should furthermore be observed that a connection by the first or second connecting line comprises the case in which further functional components might be arranged between the first end and the second end of the respective connecting line. For example, valves, sensors, regulators or the like might be arranged between the first end and the second end of the first connecting line, or between the inlet port of the coolant passage and the switchover valve.

According to some embodiments, the cooling system further comprises a reducing valve arranged in the flow of gas between the supply port and the outlet and providing a variable resistance to the flow of gas through the reducing valve; a temperature sensor for outputting a signal that represents a temperature of the object mount; and a controller configured to control the reducing valve on the basis of the signal that represents the temperature of the object mount.

In this case, the reducing valve is a valve capable of setting an amount of gas flowing through the cooling system. The reducing valve can be an electrically controllable valve, for example a magnetic valve that can be controlled by the controller for the purpose of setting a flow of gas. The temperature sensor is a sensor capable of measuring the temperature of the object mount and of communicating this temperature to the controller by way of an appropriate signal. This can be desirable for providing feedback control of the cooling system. For example, a target temperature for the object mount might be settable in such an embodiment. Then, the controller is capable of increasing a flow of gas to such an extent that the temperature sensor detects the target temperature at the object mount, or detects the target temperature over a relatively long period of time, during which the object mount has reached a thermal equilibrium.

According to some embodiments, the reducing valve can be arranged at the supply port or in the flow of gas between the supply port and the switchover valve, whereby a pressure of the gas in the whole cooling system is defined by a degree of opening of the reducing valve. In particular, the pressure of the gas that is fed to the cooling system does not depend on a gas source used or on an amount of gas contained in the source in such a case, whereby the cooling system can be operated more reliably.

According to some embodiments, the reducing valve can be arranged in the first connecting line such that, during cooling operation of the cooling system, the gas initially flows through the reducing valve after flowing through the switchover valve before it flows through the cooling mechanism. What follows from this is that, in the thawing operation, specifically the second position of the switchover valve, the gas initially flows through the object mount and the first portion of the first connecting line before the gas flows through the reducing valve. This can be desirable since the maximum pressure from the source of the gas is prevalent in the cooling system in such a case during the thawing operation, whereby frozen water can be thawed out more easily in the connecting lines.

According to some embodiments, the first connecting line comprises an insulating layer that surrounds the first connecting line in a second portion between the cooling mechanism and the object mount and that reduces a heat transfer between the second portion of the first connecting line and the surroundings. For example, the insulating layer is not present between the switchover valve and the first portion of the first connecting line. The insulating layer might moreover not be present on the second connecting line. It can be desirable for the first portion of the first connecting line to be free from an insulating layer surrounding the latter such that a heat transfer between the cooling mechanism and the gas can be performed efficiently. For example, the insulating layer is a cladding of the connecting line in the second portion using a material which has a small coefficient of thermal conductivity. An insulating layer can also be realized by virtue of the connecting line being surrounded by a housing within which a vacuum is created. A vacuum can also prevent the connecting line from icing over since the portion of the connecting lines surrounded by the insulating layer does not come into contact with suspended water from the surroundings.

According to some embodiments, the cooling mechanism comprises a cooling space. The cooling space is a volume into which a coolant, for example liquid nitrogen, can be filled. In this context, the coolant is filled into the cooling space before a start of the cooling operation. For example, the first portion of the first connecting line can be submersed in the liquid nitrogen prior to the cooling operation and also be non-destructively removed again from the latter prior to the thawing operation. As a result, the cooling mechanism can be put out of operation; this can be desirable during the thawing operation since the nitrogen which should remove the deposits in the first connecting lines is not undesirably cooled.

According to some embodiments, the switchover valve is a 5/2-port directional control valve. The 5/2-port directional control valve is a valve with five ports and two positions. The five ports are divided into two inlet ports and three outlet ports, wherein one of the three outlet ports is connected to one of the inlet ports in both positions and the other two outlet ports are each connected to one of the inlet ports in only one of the positions. Alternatively, a 4/2-port directional control valve, for example, can be used. The 4/2-port directional control valve is a valve with four ports and two positions, wherein the four ports are divided into two input ports and two output ports, and in the second position the two output ports are connected to the respective other input port in comparison with the first position.

According to some embodiments, the particle beam system furthermore comprises a vacuum cladding which delimits a vacuum chamber. For example, the vacuum cladding is a metal housing of the particle beam system. A vacuum can be created in the vacuum chamber during the operation of the particle beam system in order to reduce unwanted interactions of the particle beam with an atmosphere. In this context, it can be desirable for components whose operation does not require a vacuum to be arranged outside of the vacuum chamber since this can reduce an extent of the vacuum chamber and prevent a superfluous energy increase when creating the vacuum. For example, the switchover valve and/or the cooling mechanism can be arranged outside the vacuum chamber.

According to some embodiments, the particle beam system further comprises an object stage, which holds the object mount and for example is connected to an actuator which can be driven to displace the object mount-mounted object over the object stage relative to the lens for focusing the particle beam. For example, the object mount is held at a distance from the object stage by way of spacers in order to reduce the heat transfer between the object mount to be cooled and the object stage connected to the actuator. Fewer than ten and for example three spacers can be used to maintain the distance between the object mount and the object stage. For example, the spacers can be made of a material which has a low coefficient of thermal conductivity and are manufactured in spherical shape in order to minimize the heat transfer from the object stage to the object mount. Alternatively, the object mount might for example not be carried by an object stage but be guided into the vacuum chamber through a vacuum lock on a connection. In this case, the vacuum lock is a feedthrough through the vacuum cladding with two seals, which close with a time offset from one another when the object mount is removed from the vacuum chamber such that the vacuum prevalent within the vacuum chamber can be maintained during the removal.

According to some embodiments, a method for operating the particle beam system comprises an operation of the particle beam system in two operating modes, specifically a cooling operation and a thawing operation. In the cooling operation, the switchover valve is initially moved into the first position. Thereupon, gas is fed to the supply port and the first portion of the first connecting line is cooled using the cooling mechanism, whereby the gas flowing through the first portion of the first connecting line is cooled. The object mount and an object arranged on the object mount are then cooled by the cooled gas. The cooled object is scanned using the particle beam, and signals created by the object upon the incidence of the particle beam are captured by the detector, whereby a particle-optical image can be created. During the thawing operation, the switchover valve is initially moved into the second position. Thereupon, gas is fed to the supply port, and the object mount is heated using the gas that is fed. Heating the object mount prevents the removed deposits, which are taken up by the gas, from being deposited again in the object mount when flowing through the coolant passage, whereby a time used to remove the deposits is shortened.

The gas that is fed is nitrogen according to some embodiments. In this case, it should be observed that gases usually contain contaminants. Herein, gases in which a proportion of the contaminants vis-à-vis a proportion of the actual nitrogen is low are referred to as nitrogen. For example, the nitrogen has less than 1 volume-% of contaminants.

### BRIEF DESCRIPTION OF THE DRAWINGS

Embodiments will be explained in detail below on the basis of the figures, in which:

FIG. 1 shows a particle beam system having a cooling system according to one embodiment; and

FIG. 2 shows a flowchart for explaining a method for operating a particle beam system shown in FIG. 1.

### DETAILED DESCRIPTION

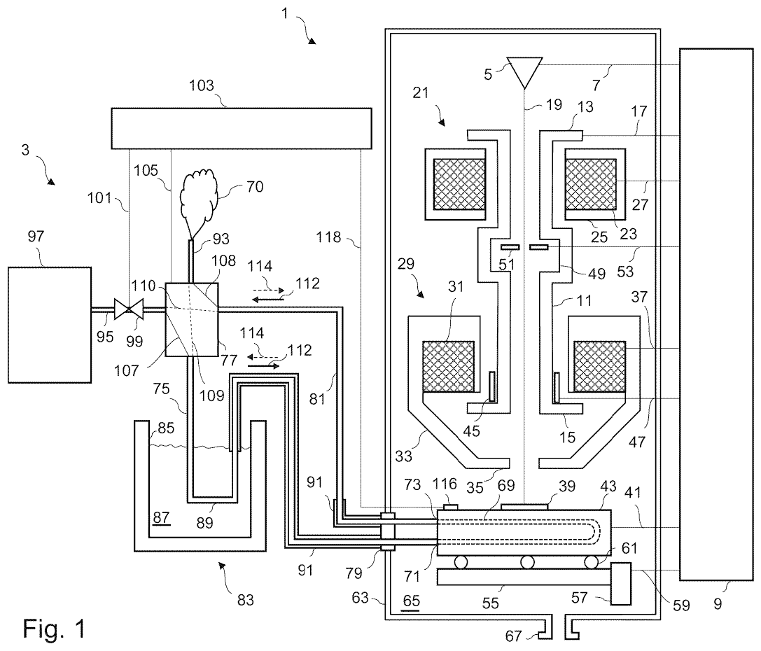

FIG. 1 shows a particle beam system 1 having a cooling system 3 according to one embodiment. The particle beam system 1 comprises a particle beam source 5 which is connected to a controller 9 via an electrical line 7. The controller 9 is capable of supplying a first electric potential to the particle beam source 5 via the electrical line 7. The particle beam system 1 further comprises a beam tube 11 having an upper end 13 and a lower end 15. The beam tube 11 is connected to the controller 9 via an electrical line 17. By way of the electrical line 17, the controller 9 is capable of supplying a second electric potential to the beam tube 11. During the operation of the particle beam system 1, the controller 9 supplies the first electric potential to the particle beam source 5, whereby particles are released from the particle beam source 5. Moreover, the controller 9 supplies the beam tube 11 with a second electric potential that differs from the first electric potential such that the particles released from the particle beam source 5 are accelerated towards the upper end 13 of the beam tube 11 and form a particle beam 19.

It should be observed that the upper end 13 of the beam tube 11 acts like an acceleration electrode in the example described herein. However, provision can be made for an additional acceleration electrode which may be comprised in the particle beam source 5, for example, in the particle beam system 1 shown in FIG. 1.

The particle beam 19 passes through a condenser lens 21 which comprises a pole shoe 25 and a coil 23. The coil 23 of the condenser lens 21 is connected to the controller 9 via an electrical line 27, with the result that this controller is capable of supplying an electric current to the coil 23 of the condenser lens 21, whereby the coil 23 of the condenser lens 21 creates a magnetic field. The magnetic field created by the coil 23 of the condenser lens 21 enters the beam tube 11 at an opening of the pole shoe 25 and influences the particle beam 19 passing through the condenser lens 21. The condenser lens 21 is used to collimate the particle beam 19. However, the condenser lens 21 can also be used to focus the particle beam 19. Even though the condenser lens 21 is depicted as a magnetic lens in FIG. 1, the condenser lens 21 might also be any other lens suitable for influencing the particle beam 19. For example, the condenser lens can be an electrostatic lens, such as a single lens.

The particle beam 19 furthermore passes through an objective lens 29 which comprises a coil 31 and a pole shoe 33 with a lower end 35. The coil 31 of the objective lens 29 is connected to the controller 9 via an electrical line 37, with the result that this controller is capable of supplying an electric current to the coil 31 of the objective lens 29, whereby the coil 31 of the objective lens 29 creates a magnetic field. The pole shoe 33 of the objective lens 29 has a lower end 35, which is arranged below the lower end 15 of the beam tube 11. The pole shoe 35 of the objective lens 29 is open towards the particle beam 19, with the result that the magnetic field created by the coil 31 of the objective lens 29 is able to enter the pathway of the particle beam 19 in order to influence the letter.

The particle beam 19 is focused on an object 39 by the objective lens 29. It should be observed that focusing of the particle beam 19 can also be performed by the condenser lens 21. Moreover, in a manner similar to the condenser lens 21, the objective lens 29 can also be an electrostatic lens, for example a single lens, rather than the magnetic lens shown in FIG. 1.

The particle beam 19 also passes through an electrostatic lens which is formed by the lower end 15 of the beam tube 11 and the object 39. Via an electrical line 41 and an object mount 43, a third potential can be supplied to the object 39 by the controller 9. In the particle beam system 1 described herein, it is desirable for the third electric potential supplied to the object 39 to correspond to a zero potential in order to avoid an energy supply by the controller 9.

An electric field between the lower end 15 of the beam tube 11 and the object 39 is defined by a difference between the second electric potential supplied to the beam tube 11 and the third electric potential supplied to the object 39. The particle beam 19 is influenced when passing through this electric field prevalent between the lower end 15 of the beam tube 11 and the object 39. This electric field creates an effect of a focusing lens. This structure can also be referred to as a combination of lens since there is a significant overlap between the electric field of the electrostatic lens and the magnetic field of the objective lens 29.

An incidence location of the particle beam 19 on the object 39 is influenced by a deflection arrangement 45. In the example shown in FIG. 1, the deflection arrangement 45 comprises a plurality of pairs of electrodes which create an electric field that deflects the particle beam 19 when passing through the electric field when, via an electrical line 47, a voltage is supplied between the electrodes of a pair by the controller 9.

When the particle beam 19 is incident on the object 39, the object 39 emits electrons which are accelerated into the beam tube 11 on account of the focusing electrostatic lens between the object 39 and the lower end 15 of the beam tube 11. The beam tube 11 also comprises a space 49 for components, in which, as shown in FIG. 1, a detector 51, for example, is arranged, the latter being connected to the controller 9 via an electrical line 53. The detector 51 comprises a detector area for detecting the electrons entering into the beam tube 11. The detector 51 creates a detector signal which represents a number of electrons incident on the detector 51 and transmits the detector signal to the controller 9 via the electrical line 53.

The particle beam system 1 creates an image of the object 39 by virtue of the controller 9 setting different voltage values at the deflection arrangement 45 and assigning each of these voltage values to a detector signal. To this end, the detector signals and the voltage values can be stored in a memory of the controller 9.

The particle beam system 1 further comprises an object stage 55. The object stage 55 can be moved by an actuator 57, wherein the actuator 57 can be activated by the controller 9 via an electrical line 59. For example, a distance between the lower end 35 of the pole shoe 33 of the object lens 29 and the object 39, which can also be referred to as the working distance, can be changed by way of the actuator 57.

The object stage 55 carries the object mount 43 at a distance which is defined by spacers 61 between the object stage 55 and the object mount 43. As shown in FIG. 1, the spacers 61 might have a spherical form in order to keep a contact area between the object mount 43 and the spacers 61, or between the object stage 55 and the spacers 61, as small as possible. Reducing this contact area reduces the heat transfer between the object stage 55 and the object mount 43 to be cooled.

The particle beam system 1 further comprises a vacuum cladding 63 which surrounds a vacuum chamber 65 in which the above-described components of the particle beam system 1, with the exception of the controller 9, are arranged. Air is sucked out of the vacuum chamber 65 using a pump (not shown) connected to a pump nozzle 67, and hence a vacuum is created.

The particle beam system 1 further comprises the cooling system 3. The cooling system 3 comprises a coolant passage 69 in the object mount 43. The object mount 43 can dissipate heat to a coolant by way of the coolant passage 69. The coolant used to this end is a gas 70, for example nitrogen. For the above-described purpose, the coolant passage 69 comprises an inlet port 71, in which the nitrogen 70 flows into the coolant passage 69 during cooling operation, and an outlet port 73, from which the nitrogen 70 flows out of the coolant passage 69 during the cooling operation.

The inlet port 71 of the coolant passage 69 is connected to a switchover valve 77 via a first connecting line 75. To this end, a first end of the connecting line 75 is connected to the input port 71 of the coolant passage 69, the connecting line 75 is guided out of the vacuum chamber 65 through a vacuum seal 79 through the vacuum cladding 63 and a second end of the connecting line 75 is connected to the switchover valve 77. The vacuum seal 79 is a seal which hermetically closes off an opening in the vacuum cladding 63. For example, the vacuum seal 79 is a rubber seal or a metal seal. For example, the vacuum seal 79 shown in FIG. 1 is a double feedthrough which in addition to the first connecting line 75 also guides a second connecting line 81 out of the vacuum chamber 65 through the vacuum cladding 63. The second connecting line 81 is connected at a first end to the outlet port 73 of the coolant passage 69 and connected at a second end to the switchover valve 77.

The cooling system 3 also comprises a cooling mechanism 83 which has a cooling space 85. Liquid nitrogen 87 is filled into the cooling space 85, for example before the cooling system is put into operation, and a first portion 89 of the first connecting line 75 is submersed in the liquid nitrogen 87. The nitrogen 70 flowing through the first portion 89 of the first connecting line 75 is thereby cooled by the liquid nitrogen 87.

Further, a second portion of the first connecting line 75 and a portion of the second connecting line 81 have an insulating layer 91. The insulating layer 91 reduces a heat transfer from surroundings to the second portion of the first connecting line 75 and to the portion of the second connecting line 81, which are surrounded by the insulating layer 91. This reduces heating of the nitrogen 70 in the second portion of the first connecting line 75. For example, the insulating layer 91 can be a cladding into which a vacuum is pumped such that the second portion of the first connecting line 75 and the portion of the second connecting line 81 are surrounded and insulated by a vacuum. Moreover, such a setup prevents external icing over of the second portion of the first connecting line 75 and of the portion of the second connecting line 81, which are surrounded by the insulating layer 91, since these are not connected to suspended water from the surroundings as a result of being bordered by the vacuum.

In the case in which the insulating layer 91 is realized with the above-described vacuum, the insulating layer 91 can be connected via an opening to the vacuum chamber 65 of the particle beam system 1, with the result that the vacuum is created by operating the pump (not shown) via the pump nozzle 67. Alternatively, the insulating layer 91 can have additional pump nozzles, to which a further pump is connected for the purpose of creating a vacuum in the insulating layer 91.

The cooling system 3 also comprises an outlet 93, from which the nitrogen 70 is released. Moreover, the cooling system 3 comprises a supply port 95 for feeding the nitrogen 70 into the cooling system 3. To this end, the supply port 95 is connected to a nitrogen reservoir 97, for example a nitrogen flask or a nitrogen tank. To be able to set an inflow of nitrogen 70 from the nitrogen reservoir 97, the supply port 95 is connected to the switchover valve 77 via a reducing valve 99. For example, the reducing valve 99 is a magnetic valve, which can be controlled electrically. For control purposes, the reducing valve 99 is connected to a controller 103 via an electrical line 101. For example, the controller 103 determines a current that should be supplied to a magnetic valve in order to attain a target flow of the nitrogen 70 and feeds the determined current to the reducing valve 99.

The switchover valve 77 is connected for control purposes to the controller 103 via an electrical line 105. The switchover valve 77 shown in FIG. 1 is a 4/2-port directional control valve; however, the switchover valve 77 can also be of a different type, for example a 5/2-port directional control valve. For a simplified illustration, the 4/2-port directional control valve as shown in FIG. 1 is described below.

The switchover valve 77 comprises four ports, which are connected to the supply port 95, the outlet 93, the first connecting line 75 and the second connecting line 81. The switchover valve 77 further has a first position and a second position. The first position is represented by the solid paths 107 and 108, and the second position is represented by the dashed paths 109 and 110. Should the switchover valve 77 be in the first position represented by the solid paths 107 and 108, the supply port 95 is connected to the first connecting line 75, and the outlet 93 is connected to the second connecting line 81. Accordingly, in the first position of the switchover valve 77, the nitrogen 70 flows out of the nitrogen reservoir 97 into the first connecting line 75. The nitrogen 70 is thereupon cooled in the first portion 89 of the first connecting line 75 and flows through the coolant passage 69 in the object mount 43, whereby the object mount 43 and the object 39 arranged on the object mount 43 are cooled. Subsequently, the nitrogen 70 flows through the second connecting line 81 to the outlet 93 and is released into the surroundings there. The flow of the nitrogen 70 in the first position of the switchover valve 77 is represented by solid arrows 112 in FIG. 1.

Since for example water is contained in the nitrogen 70 as a minor contamination, the water freezes upon entry of the nitrogen 70 into the first portion 89 of the first connecting line 75 on account of the low temperature caused by the liquid nitrogen 87. Hence the frozen water is deposited in the first portion 89 of the first connecting line 75. In the case of a lengthy operation of the particle beam system 1 in the first position of the switchover valve 77, an increasing amount of ice collects in the first connecting line 75, whereby the first connecting line 75 is blocked and a cooling performance of the cooling system 3 is impaired.

In order to remove the deposits, the controller 103 is able to change the position of the switchover valve 77 by way of an electrical line 105, and hence put the switchover valve 77 into the second position. Additionally, the cooling mechanism 83 are taken away by virtue of the first portion 89 of the first connecting line 75 being taken out of the liquid nitrogen 87. It should be observed that removal of the cooling mechanism 83 is not mandatory. In a case in which the cooling mechanism 83 is a Peltier cooling mechanism for example, it is sufficient for the cooling mechanism 83 to have a lesser cooling power such that the nitrogen 70 is only cooled slightly during the operation of the switching valve 77 in the second position.

In the second position of the switchover valve 77 represented by the dashed paths 109 and 110, the supply port 95 is connected to the second connecting line 81, and the outlet 93 is connected to the first connecting line 75. Accordingly, the nitrogen 70 flows from the nitrogen reservoir 97 into the second connecting line 81 in the second position of the switchover valve 77. Thereupon, the uncooled nitrogen 70 flows through the coolant passage 69 in the object mount 43 and warms the latter. Thereupon, the nitrogen 70 flows through the first connecting line 75 and heats the first portion 89 of the first connecting line 75, whereby the deposits are dissolved. The dissolved deposits are then released to the surroundings by the nitrogen 70 flowing through the first connecting line 75 and the outlet 93. The flow of the nitrogen 70 in the second position of the switchover valve 77 is represented by dashed arrows 114 in FIG. 1.

It is for example ensured that the dissolved deposits cannot be deposited in the cooling system 3 again as a result of the reversal of the flow direction of the nitrogen 70 in the first connecting line 75 and the second connecting line 81 in the second position of the switchover valve 77 since the object mount 43 or the first connecting line 75 is heated using the nitrogen 70 which does not yet contain any dissolved deposits. Since the dissolved deposits are removed directly from the cooling system 3 by the particle beam system 1, removal of the deposits can be carried out quickly and efficiently.

The cooling system 3 further comprises a temperature sensor 116 which is attached to the object mount 43 in order to detect a temperature of the object mount 43. For example, the temperature sensor 116 is a resistance temperature sensor. The temperature sensor 116 creates a signal which represents the temperature of the object mount 43 and transmits the signal to the controller 103 via an electrical line 118. For example, the temperature sensor 116 serves to determine whether there should be a switchover into the second position of the switchover valve 77 or into the first position of the switchover valve 77, as will be described in detail below.

It should be observed that the controller 103 need not necessarily be separate from the controller 9 as shown in FIG. 1. Moreover, a plurality of components of the cooling system 3 depicted outside of the vacuum chamber 65 in FIG. 1 might also be arranged within the vacuum chamber 65.

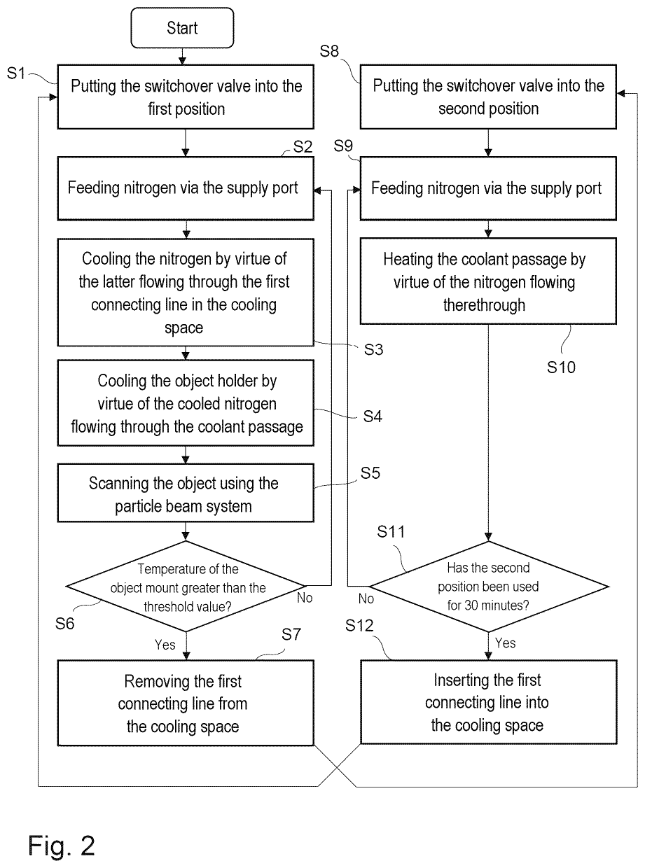

FIG. 2 shows a flowchart for explaining a method for operating the particle beam system 1 shown in FIG. 1. In this case, the method comprises an operation of the particle beam system 1 in a first operating mode, which comprises steps S1 to S6, an operation of the particle beam system 1 in a second operating mode, which comprises steps S8 to S11, and steps S7 and S12 for switching over between the first operating mode and the second operating mode.

In step S1, the controller 103 puts the switchover valve 77 into the first position, which is depicted by the solid paths 107 and 108 in FIG. 1. Thereupon, the controller 103 sets the flow of the nitrogen 70 at the reducing valve 99 in step S2, the flow then flowing from the nitrogen reservoir 97 to the first connecting line 75 through the switchover valve 77.

The nitrogen 70 flowing through the first connecting line 75 is cooled by the cooling mechanism 83 in step S3 when flowing through the first portion 89 of the first connecting line 75. In the case of the particle beam system 1, the nitrogen 70 is cooled by liquid nitrogen 87 for example when flowing through the first portion 89 of the first connecting line 75. In step S4, the nitrogen 70 then flows through the coolant passage 69 in the object mount 43 and cools the object mount 43 and the object 39 situated thereon. The nitrogen 70 is thereupon released to the surroundings.

The cooled object 39 can then serve to record a particle-microscopic image using the particle beam system 1. For example, the controller 9 scans with the particle beam 19 a region on the object 39 in step S5 by virtue of the controller 9 applying a plurality of successive voltages to the electrodes of the deflection arrangement 45 and assigning the voltages to the respective captured detector signal.

During the operation of the particle beam system 1 in the first operating mode, the controller 103 monitors a temperature of the object mount 43 using the temperature sensor 116. Should the first portion 89 of the first connecting line 75 have a large amount of deposits, the cooling power of the cooling system 3 is limited, and the object mount 43 cannot be cooled sufficiently. The temperature of the object mount 43 increases accordingly, and this is detected by the temperature sensor 116. For this reason, the controller 103 evaluates the signal of the temperature sensor 116 in step S6 and compares the signal with a predetermined threshold value. For example, such a threshold value is 5° C. greater than a target temperature of the object mount 43. If the threshold value is not exceeded by the measured temperature of the object mount 43, then the first operating mode is still carried out going forward. More precisely, nitrogen 70 continues to be fed, the nitrogen 70 is cooled, the object mount 43 is cooled and the object 39 is scanned using the particle beam system 1, as described in steps S2 to S5 in FIG. 2.

If the threshold value is exceeded by the measured temperature of the object mount 43, then there is a switchover to the second operating mode. To this end, the first portion 89 of the first connecting line 75 is initially removed from the liquid nitrogen 87 in step S7. For example, this can be implemented by a user of the particle beam system 1 after they were informed via a user interface that a removal of the first portion 89 of the first connecting line 75 from the liquid nitrogen 87 is desired. Alternatively, the first portion 89 of the connecting line 75 can be secured to a guide which can be moved out of the cooling mechanism 83 by way of an actuator. Such an actuator can be controlled by the controller 103.

After the first portion 89 of the first connecting line 75 has been removed from the cooling mechanism 83, the controller 103 continues with step S8, in which the controller 103 puts the switchover valve 77 into the second position, which is represented in FIG. 1 by the dashed paths 109 and 110. Thereupon, the controller 103 sets the flow of nitrogen 70 on the reducing valve 99 in step S9.

Since the direction of flow of the nitrogen 70 has been reversed in relation to the first position of the switchover valve 77 as a result of the second position of the switchover valve 77, as depicted by the solid arrows 112 and for example the dashed arrows 114 in FIG. 1, the uncooled nitrogen 70 flows through the coolant passage 69 in the object mount 43, as described in step S10 in FIG. 2. The coolant passage 69 and the object holder 43 are heated as a result. The uncooled nitrogen 70 also heats the first portion 89 of the first connecting line 75 and removes deposits present in the first portion 89 of the first connecting line 75.

The controller 103 monitors the duration of the operation of the particle beam system 1 in the second operating mode. For example, the controller 103 carries out a check in step S11 as to whether a predetermined operating duration has elapsed since the start of the operation of the particle beam system 1 in the second operating mode. For example, the predetermined operating duration is half an hour. If the predetermined operating duration since the start of the operation of the particle beam system 1 in the second operating mode has not elapsed, then the controller 103 carries out the operation of the particle beam system 1 in the second operating mode. More precisely, the feed of the nitrogen 70 and the heating of the coolant passage 69 through the object mount 43 in steps S9 and S10 are repeated, as is the check regarding the duration of the operation of the particle beam system 1 in the second operating mode in step S11.

If the controller 103 in step S11 determines that the predetermined operating duration since the start of the operation of the particle beam system 1 in the second operating mode has elapsed, then there is a switchover to the first operating mode. To this end, the first portion 89 of the first connecting line 75 is submersed in the liquid nitrogen 87 in step S12, and the controller 103 continues with step S1. In a manner similar to what was described in relation to step S7, the first portion 89 of the first connecting line 75 can be submersed in the liquid nitrogen 87 by a user after they were notified that the insertion of the first portion 89 of the first connecting line 75 into the cooling mechanism 83 is desired, or a guide by which step S12 can be performed by the controller 103 might be present. It should be observed that the above-described predetermined operating duration of half an hour serves illustrative purposes, and any other value can be chosen for the operating duration. Moreover, it should also be observed that the temperature of the object mount 43 can also be monitored using the temperature sensor 116 in step S11, similar to what occurred in step S6. In such a case, the controller 103 can for example compare the temperature value measured by the temperature sensor 116 with a room temperature, a temperature of the nitrogen 70 when leaving the nitrogen reservoir 97, or the like.

It should be observed that the cooling system 3 might comprise further sensors that create signals that can be used by the controller 103 in step S6 and/or in step S11. For example, a further temperature sensor can be arranged on the first portion 89 of the first connecting line 75 and can be connected to the controller 103 via an electrical line. In that case, the controller 103 can compare a temperature measured by this temperature sensor on the first portion 89 of the first connecting line 75 with a predetermined threshold value in step S6 and/or in step S11. For example, the predetermined threshold value is a value slightly above the usual temperature of liquid nitrogen, and can be −190° C. If the temperature measured on the first portion 89 of the first connecting line 75 exceeds the threshold value in step S6, then the process continues with step S7 as described above. Otherwise, the process continues with steps S2 to S5, as described above.

Moreover, the controller 103 can compare the temperature measured on the first portion 89 of the first connecting line 75 with a second threshold value which is higher than the aforementioned threshold value and for example represents a room temperature. As a result, the controller 103 can determine whether step S7 is desired. For example, the controller 103 need not notify the user of the particle beam system 1 with regards to the desire to remove the first portion 89 of the first connecting line 75 from the liquid nitrogen 87 and instead skip step S7 if the temperature measured at the first portion 89 of the first connecting line 75 is greater than the second threshold value, i.e. greater than the room temperature for example.

If the temperature measured on the first portion 89 of the first connecting line 75 drops below the threshold value in step S11, then the process continues with step S12, as described above. Otherwise, the process continues with steps S9 and S10, as described above. Using such a control of the cooling system 3, it is possible to automatically switch from the cooling operation of the cooling system 3 to the thawing operation if the first portion 89 of the first coolant line 75 is removed from the liquid nitrogen 87 or the liquid nitrogen 87 has been consumed.

A plurality of further embodiments are conceivable. For example, the controller 103 and the controller 9 could be implemented in a common controller, for example an all-purpose computer. Moreover, the coolant is not restricted to nitrogen. The particle beam system 1 disclosed herein can be implanted for any coolant in which contaminations in the coolant deposit on account of the coolant being cooled.

What is claimed is:

1. A particle beam system, comprising:
an object mount configured to mount an object;
a particle beam source configured to create a particle beam;
a lens configured to focus the particle beam on the object;
a detector configured to detect signals created via the interaction of the particle beam and the object; and
a cooling system configured to cool the object mount, the cooling system comprising:
a coolant passage through the object mount, the coolant passage comprising an inlet port and an outlet port;
a supply port configured to feed a gas;
an outlet configured to remove the gas;
a switchover valve comprising a first position and a second position;
a first connecting line, the first connecting line comprising a first end connected to the inlet port of the coolant passage, and the first connecting line comprising a second end connected to the switchover valve;
a second connecting line, the second connecting line comprising a first end connected to the outlet port of the coolant passage, and the second connecting line comprising a second end connected to the switchover valve; and
a cooling mechanism configured to cool at least a first portion of the first connecting line,
wherein:
when the switchover valve is in the first position: the switchover valve connects the supply port to the second end of the first connecting line; and the switchover valve connects the outlet to the second end of the second connecting line; and
when the switchover valve is in the second position: the switchover valve connects the supply port to the second end of the second connecting line; and the switchover valve connects the outlet to the second end of the first connecting line.

2. The particle beam system of claim 1, wherein the cooling system further comprises:
a reducing valve along a flow of gas between the supply port and the outlet, the reducing valve configured to provide variable resistance to the flow of gas through the reducing valve;
a temperature sensor configured to output a signal representing a temperature of the object mount; and
a controller configured to control the reducing valve based on the signal representing the temperature of the object mount.

3. The particle beam system of claim 2, wherein, when the switchover valve is in the first position: the reducing valve is along the flow of gas between the supply port and the switchover valve; and the reducing valve is along the flow of gas before the cooling mechanism.

4. The particle beam system of claim 2, wherein the reducing valve is along the flow of gas between the switchover valve and the cooling mechanism.

5. The particle beam system of claim 1, wherein the first connecting line comprises an insulating layer surrounding the first connecting line in a second portion between the cooling mechanism and the object mount.

6. The particle beam system of claim 1, wherein the cooling mechanism comprises a cooling space through which a first portion of the first connecting line passes.

7. The particle beam system of claim 6, wherein the first portion of the first connecting line is free from an insulating layer surrounding it.

8. The particle beam system of claim 6, wherein the cooling space is configured to accommodate liquid nitrogen.

9. The particle beam system of claim 6, wherein the first portion of the first connecting line is non-destructively removable from the cooling space and subsequently re-insertable therein.

10. The particle beam system of claim 1, wherein the switchover valve comprises a 5/2-port directional control valve.

11. The particle beam system of claim 1, further comprising a vacuum cladding delimiting a vacuum chamber, wherein the object mount is within the vacuum chamber, and the switchover valve is outside of the vacuum chamber.

12. The particle beam system of claim 11, wherein the cooling mechanism is outside of the vacuum chamber.

13. The particle beam system of claim 1, further comprising an object stage that is displaceable relative to the lens, wherein the object stage carries the object mount.

14. The particle beam system of claim 13, wherein the object mount is thermally insulated from the object stage.

15. The particle beam system of claim 14, wherein:
the object mount comprises a main face facing the object stage;
the object stage comprises a main face facing the object mount;
the particle beam system comprises a total of less than 10 spacers between the object mount and the object stage to maintain a distance between the main face of the object mount and the main face of the object stage.

16. A method, comprising:
providing the particle beam system of claim 1;
operating the particle beam system in the first operating mode, comprising
moving the switchover valve into the first position;
feeding gas to the supply port;
cooling the first portion of the first connecting line using the cooling mechanism;
cooling the object mount and an object on the object mount using the gas cooled in the first connecting line; and
scanning the particle beam over the object and detecting signals using the detector; and
operating the particle beam system in the second operating mode, comprising:
moving the switchover valve into the second position;
feeding gas to the supply port; and
heating the object mount using the gas that is fed.

17. The method of claim 16, wherein the cooling mechanism is not operated in the second operating mode.

18. The method of claim 16, wherein:
the cooling mechanism comprises a cooling space through which a first portion of the first connecting line passes; and
the method further comprises, after operating the particle beam system in the first operating mode and before operating the particle beam system in the second operating mode, removing the first portion of the first connecting line from the cooling space.

19. The method of claim 16, wherein:
the cooling mechanism comprises a cooling space through which a first portion of the first connecting line passes; and
the method further comprises, before operating the particle beam system in the first mode, filling the cooling space with liquid nitrogen.

20. The method of claim 19, further comprising:
after operating the particle beam system in the first operating mode and before operating the particle beam system in the second operating mode, taking of the first portion of the first connecting line from the cooling space; and
after operating the particle beam system in the second operating mode and before operating the particle beam system in the first operating mode, inserting the first portion of the first connecting line into the cooling space.

21. The method of claim 16, wherein the gas comprises nitrogen.
